(19) United States
(12) Patent Application Publication
(10) Pub. No.: US 2016/0018441 A1
(43) Pub. Date: Jan. 21, 2016

(54) PROBE CARD, AND CONNECTING CIRCUIT BOARD AND SIGNAL FEEDING STRUCTURE THEREOF

(71) Applicant: MPI CORPORATION, Zhubei (TW)

(72) Inventors: WEI-CHENG KU, Zhubei (TW); HAO WEI, Zhubei (TW); JUN-LIANG LAI, Zhubei (TW); CHIH-HAO HO, Zhubei (TW)

(73) Assignee: MPI CORPORATION, Zhubei (TW)

(21) Appl. No.: 14/797,582

(22) Filed: Jul. 13, 2015

(30) Foreign Application Priority Data
Jul. 18, 2014 (TW) 103124721

(51) Int. Cl. G01R 1/067; G01R 31/02

(52) U.S. Cl. CPC G01R 1/06794; G01R 31/02

(57) ABSTRACT

A probe card includes a connecting circuit board, a connector, and a probe. The connecting circuit board includes a substrate having a signal via and a plurality of ground vias, a signal feeding structure disposed on the substrate, and a connecting layer having the connector disposed thereon. The signal feeding structure includes a signal feeding pad and a ground pad, which is connected to the ground via, and has a matching compensation opening having a first side and a second side wider than the first side. The signal feeding pad does not contact the ground pad, and has a first end and a second end wider than the first end. The second end is connected to the signal via. The connecting layer has a signal connecting portion connected to the signal via, and a ground connecting portion connected to the ground vias. The probe is connected to the first end.

### BACKGROUND OF THE INVENTION

1. Technical Field

The present invention relates generally to the structure of a probe card, and more particularly to a probe card, and its connecting circuit board and signal feeding structure.

2. Description of Related Art

To test if every electronic component of a device-under-test (DUT) is electrically connected correctly, a widely used method is to apply a probe card between a test machine and the DUT, wherein the probe card is functioned as a transmission interface of test signals. In order to have accurate test results, the impedance of a probe card has to match that of the test machine and the DUT to effectively transmit high-frequency test signals.

The impedance matching between a probe card, a test machine, and a DUT can be affected by many factors such as the structural differences between different kinds of probe cards. Typically, the factors which mostly affect the impedance matching are related to the difference between the diameter of a probe and the width of the pad on a circuit board. When an electrical signal is transmitted to a probe from a circuit board, it may be interfered due to the difference between the probe diameter and the width of the pad, and such problem may lead to disorder among electrical signals, and therefore the loss rate may increase, while the accuracy of test may decrease as well.

### BRIEF SUMMARY OF THE INVENTION

In view of the above, the primary objective of the present invention is to provide a probe card, and a connecting circuit board and a signal feeding structure of the probe card, which is helpful to transmit electrical signals more smoothly without letting the electrical signals interfere each other or become disorder. The accuracy of transmitting electrical signals can be increased as a result, and therefore the goal of impedance matching can be effectively achieved.

The present invention provides a probe card, which is adapted to be provided between a DUT and a test machine, including a connecting circuit board, a connector, and a probe. The connecting circuit board includes a substrate, a signal feeding structure, and a connecting layer, wherein the substrate has a first surface and a second surface, and the substrate has a plurality of ground vias and a signal via which communicate the first surface and the second surface; the signal feeding structure is made of a conductive material, and is disposed on the first surface of the substrate; the signal feeding structure comprises a ground pad and a signal feeding pad, wherein the ground pad is connected to the plurality of ground vias, and has a matching compensation opening; the matching compensation opening has a first side and a second side, wherein a width of the first side is less than a width of the second side; the signal feeding pad is located in the matching compensation opening without contacting the ground pad; the signal feeding pad has a first end and a second end, wherein the first end is toward the first side, while the second end is toward the second side, and is connected to the signal via; a width of the second end is greater than a width of the first end, and is no less than an aperture of the signal via; a first distance is formed between the first end a wall of the first side, and a second distance is formed between the second end and a wall of the second side, wherein the second distance is longer than the first distance; the connecting layer is made of a conductive material, and is disposed on the second surface of the substrate, wherein the connecting layer has a signal connecting portion and a ground connecting portion which are mutually separated; the signal connecting portion is connected to the signal via, and the ground connecting portion is connected to the plurality of ground vias. The connector is disposed on the connecting layer, wherein the connector is adapted to be electrically connected to the test machine, and has a signal transmitting portion and a ground transmitting portion; the signal transmitting portion is connected to the signal connecting portion, and the ground transmitting portion is connected to the ground connecting portion of the connecting layer. The probe has a point end and a connect end, wherein the point end is adapted to touch the DUT, and the connect end is connected to the first end of the signal feeding pad; a diameter of the connect end is no greater than the width of the first end.

The present invention further provides a connecting circuit board, which is adapted to be provided between a probe and a connector, wherein the probe has a connect end, and the connector has a signal transmitting portion and a ground transmitting portion. The connecting circuit board includes a substrate, a signal feeding structure, and connecting layer. The substrate has a first surface and a second surface, wherein the substrate has a plurality of ground vias and a signal via which communicate the first surface and the second surface. The signal feeding structure is made of a conductive material, wherein the signal feeding structure is disposed on the first surface of the substrate; the signal feeding structure comprises a ground pad and a signal feeding pad, wherein the ground pad is connected to the plurality of ground vias, and has a matching compensation opening; the matching compensation opening has a first side and a second side, wherein a width of the first side is less than a width of the second side; the signal feeding pad is located in the matching compensation opening without contacting the ground pad; the signal feeding pad has a first end and a second end, wherein the first end is toward the first side, and is adapted to be connected to the connect end of the probe; a width of the first end is no less than a diameter of the connect end; the second end is toward the second side, and is connected to the signal via; a width of the second end is greater than a width of the first end, and is no less than an aperture of the signal via; a first distance is formed between the first end a wall of the first side, and a second distance is formed between the second end and a wall of the second side, wherein the second distance is longer than the first distance. The connecting layer is made of a conductive material, wherein the connecting layer is disposed on the second surface of the substrate, wherein the connecting layer has a signal connecting portion and a ground connecting portion which are mutually separated; the signal connecting portion is connected to the signal via and the signal transmitting portion, and the ground connecting portion is connected to the plurality of ground vias and the ground transmitting portion.

The present invention further provides a signal feeding structure, which is adapted to connect a connect end of a probe and a signal via of a substrate, including a ground pad and a signal feeding pad. The ground pad is made of a conductive material, wherein the ground pad is disposed on the substrate, and has a matching compensation opening which goes through the ground pad; the matching compensation opening has a first side and a second side, wherein a width of the first side is less than a width of the second side. The signal feeding pad is made of a conductive material, wherein the signal feeding pad is disposed on the substrate and is in the matching compensation opening without contacting the ground pad; the signal feeding pad has a first end and a second end, wherein the first end is toward the first side, and is adapted to be connected to the connect end of the probe; a width of the first end is no less than a diameter of the connect end; the second end is toward the second side, and is connected to the signal via; a width of the second end is greater than a width of the first end, and is no less than an aperture of the signal via; a first distance is formed between the first end a wall of the first side, and a second distance is formed between the second end and a wall of the second side, wherein the second distance is longer than the first distance.

Whereby, with the aforementioned design, electrical signals can be transmitted more smoothly without letting the electrical signals interfere each other or become disorder. As a result, the accuracy of transmitting electrical signals can be increased, and therefore the goal of impedance matching can be effectively achieved.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a perspective view of a first preferred embodiment of the present invention;

FIG. 2 is an exploded view of the first preferred embodiment of the present invention;

FIG. 3 is an exploded view of the connecting circuit board of the first preferred embodiment;

FIG. 4 is a schematic diagram of the substrate of the first preferred embodiment;

FIG. 5 is a schematic diagram of the signal feeding structure of the first preferred embodiment;

FIG. 6 is an enlarged view at the first side of FIG. 5;

FIG. 7 is an enlarged view at the second side of FIG. 5;

FIG. 8 is a schematic diagram of the connecting layer of the first preferred embodiment;

FIG. 9 is a schematic diagram of a second preferred embodiment of the present invention; and

FIG. 10 is a schematic diagram of a third preferred embodiment of the present invention.

### DETAILED DESCRIPTION OF THE INVENTION

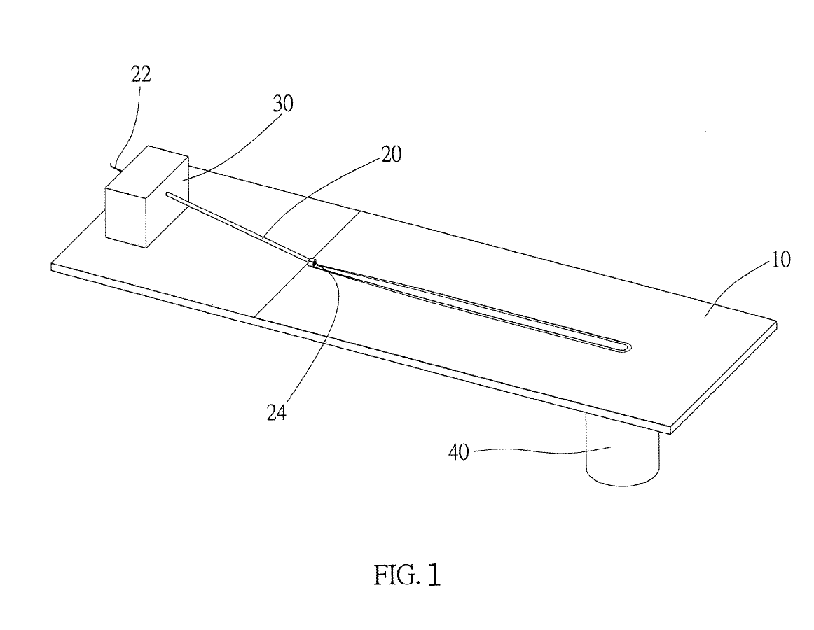

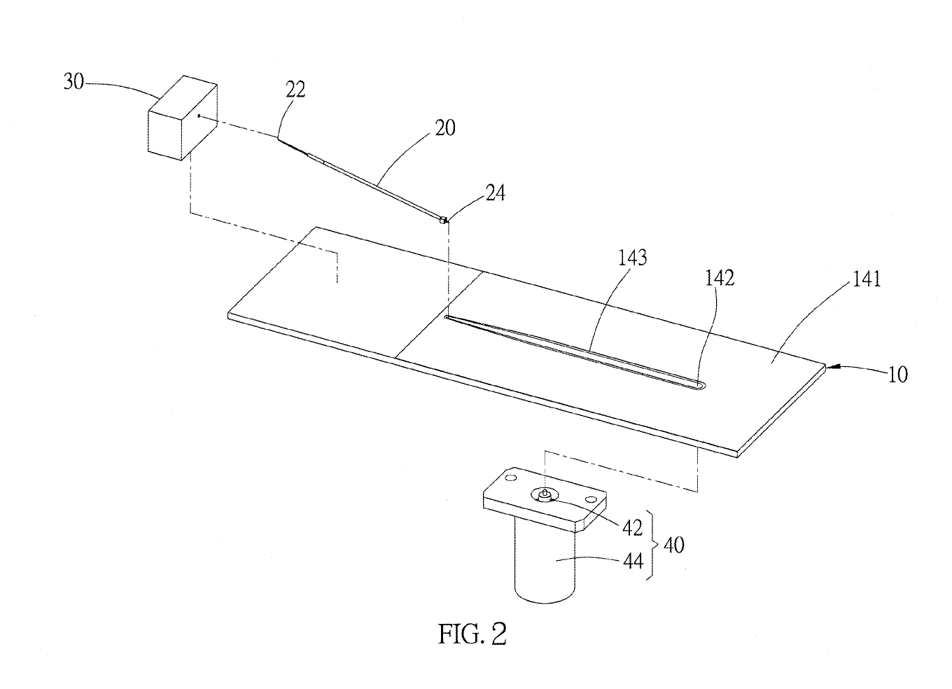

As shown in FIG. 1 and FIG. 2, a probe card of a first preferred embodiment of the present invention is adapted to be applied between a device under test (i.e., a DUT, which is not shown) and a test machine (not shown), and includes a connecting circuit board 10, a probe 20, a probe holder 30, and a connector 40.

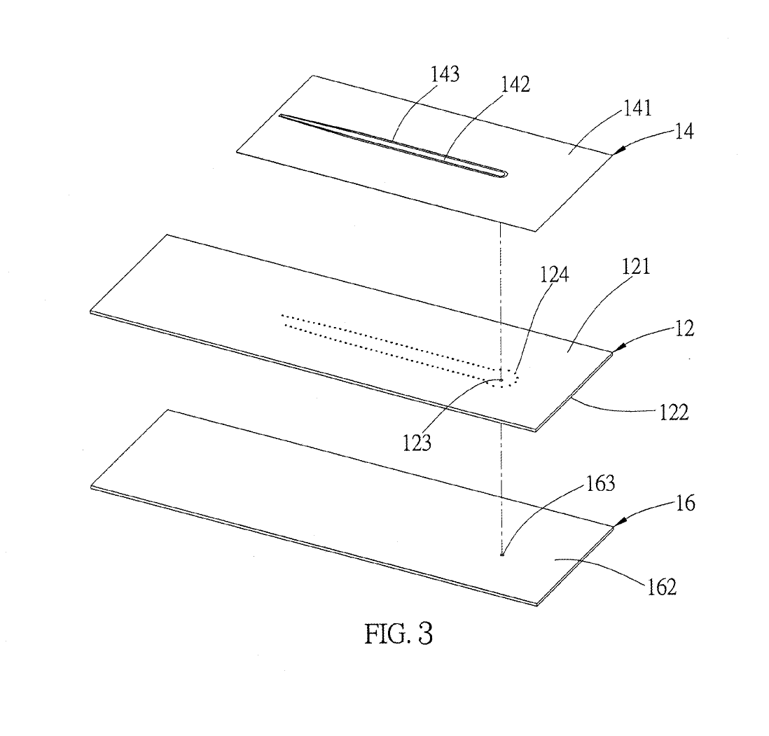

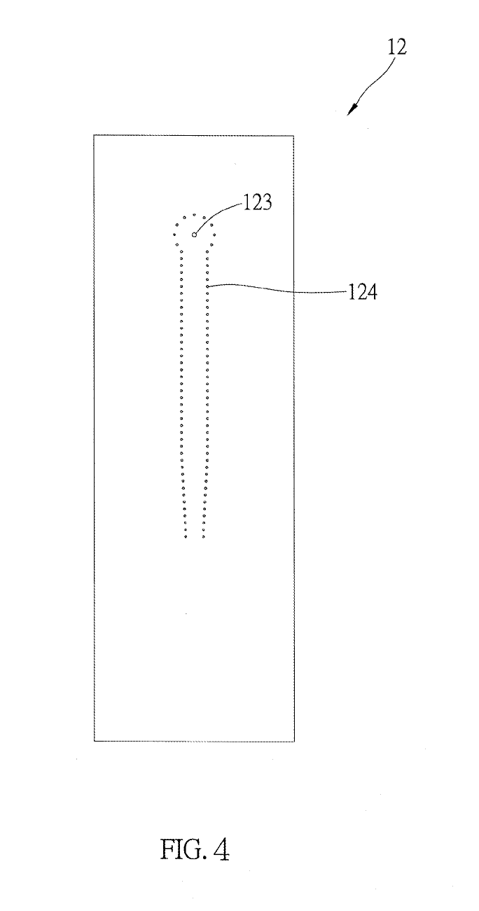

As shown in FIG. 3, the connecting circuit board 10 includes a substrate 12, a signal feeding structure 14, and a connecting layer 16. The substrate 12 has a first surface 121 and a second surface 122. The substrate 12 has a signal via 123 and a plurality of ground vias 124 thereon, wherein the signal via 123 and the plurality of ground vias 124 all communicate the first surface 121 and the second surface 122, as shown in FIG. 4. Furthermore, in the first preferred embodiment, the plurality of ground vias 124 are arranged to surround a region, in which the signal via 123 are located, and an aperture of the signal via 123 is greater than that of each of the ground vias 124.

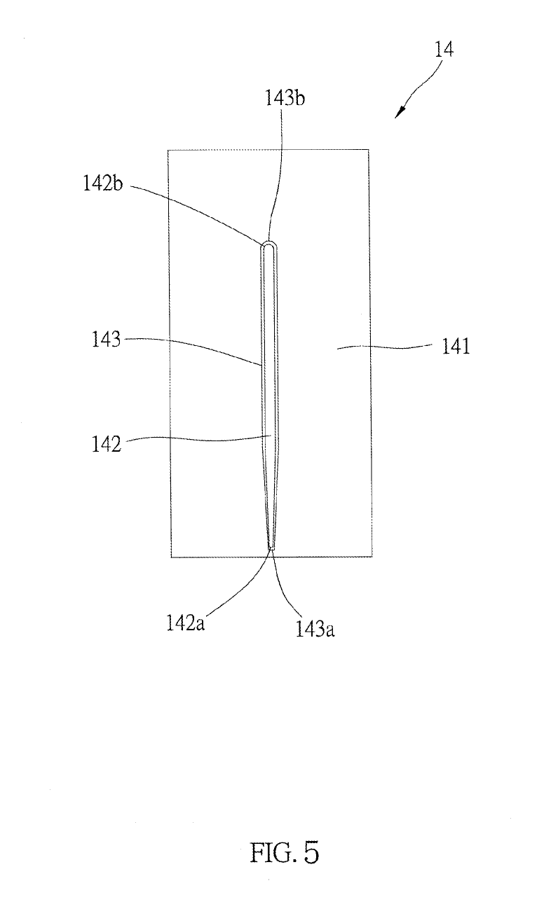

The signal feeding structure 14 is made of a conductive material, and is disposed on the first surface 121 of the substrate 12. As shown in FIG. 5, the signal feeding structure 14 includes a ground pad 141 and a signal feeding pad 142, wherein the ground pad 141 is connected to the ground vias 124, and has a matching compensation opening 143. The matching compensation opening 143 has a first side 143a and a second side 143b, wherein a width A1 of the first side 143a is less than a width A2 of the second side 143b. In addition, in the first preferred embodiment, a width of the matching compensation opening 143 between the second side 143b and the first side 143a is between the width A1 of the first side 143a and the width A2 of the second side 143b. The width of the matching compensation opening 143 is preferred to be gradually narrower from the second side 143b toward the first side 143a.

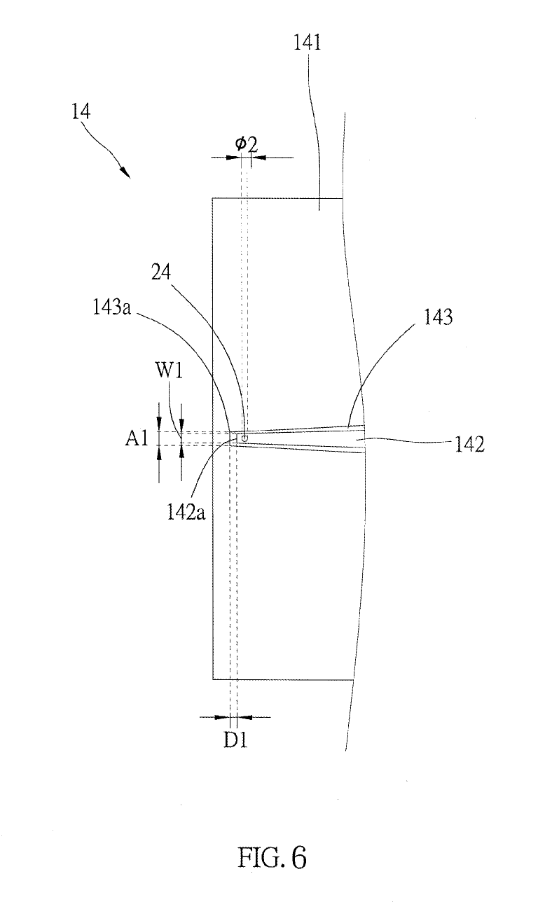

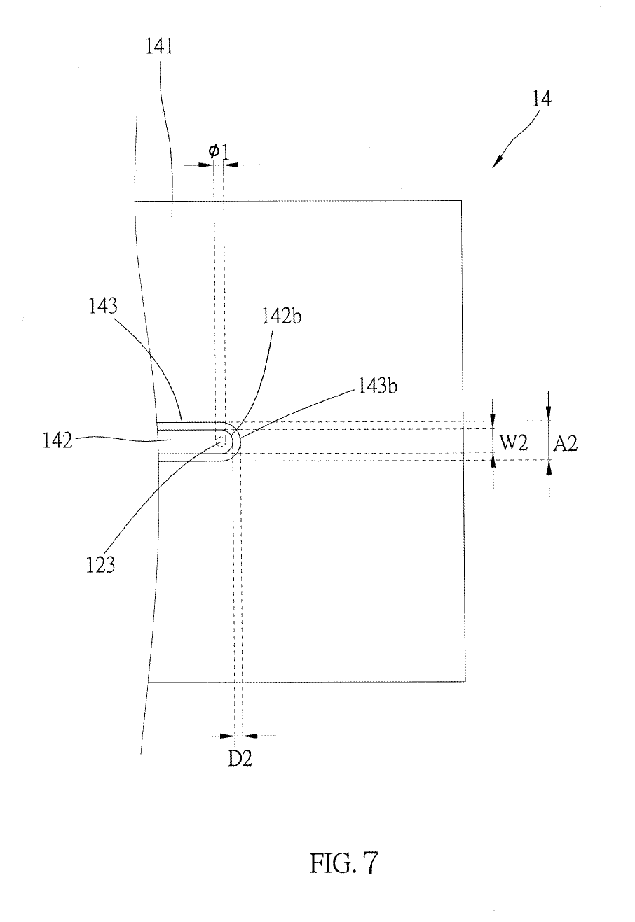

The signal feeding pad 142 is located in the matching compensation opening 143 without contacting the ground pad 141, and a shape thereof is similar to a shape of the matching compensation opening 143. An area of the signal feeding pad 142 is smaller than an area of the region surrounded by the ground vias 12. More specifically, the signal feeding pad 124 is located within a projection range of the region. In addition, as shown in FIG. 6 and FIG. 7, the signal feeding pad 142 has a first end 142a and a second end 142b, wherein the first end 142a is toward the first side 143a, and the second end 142b is toward the second side 143b and is connected to the signal via 123. A width W2 of the second end 142b is greater than a width W1 of the first end 142a, and is no less than the aperture φ1 of the signal via 123. Preferably, the width W2 is slightly greater than the aperture φ1. Whereby, when electrical signals passing through where the second end 142b and the signal via 123 are connected, the problem of current disorder which may happen due to excessive difference between cross-sectional areas can be prevented. As a result, current can flow through more smoothly. In addition, in the first preferred embodiment, a width of the signal feeding pad 142 between the second end 142b and the first end 142a is between the width W1 of the first end 142a and the width W2 of the second end 142b. The width of the signal feeding pad 142 is preferred to be gradually narrower from the second end 142b toward the first end 142a.

With the aforementioned design, a first distance D1 is formed between the first end 142a and a wall at the first side 143a, and a second distance D2 is formed between the second end 142b and the wall at the second side 143b, wherein the second distance D2 is greater than the first distance D1. In the first preferred embodiment, the distance between the signal feeding pad 142 and the wall of the matching compensation opening 143 is gradually narrower from the second end 142b to the first end 142a (i.e., from the second side 143b to the first side 143a).

Since the width of the signal feeding pad 142 is gradually narrower from the second end 142b toward the first end 142a, the parasitic inductance at each portion thereof gradually increases from the second end 142b toward the first end 142a. In addition, since the distance between the signal feeding pad 142 and the wall of the matching compensation opening 143 is gradually narrower from the second end 142b toward the first end 142a, the parasitic capacitance between the signal feeding pad 142 and the matching compensation opening 143 gradually increases from the second end 142b toward the first end 142a.

In this way, as it can be seen from the formula of impedance: Z=√(L/C) without taking resistance into account, if the parasitic capacitance C generated between the signal feeding pad 142 and the wall of the matching compensation opening 143 due to the distance therebetween changes in proportion to the parasitic inductance L generated by the width of the signal feeding pad 142, the corresponding impedance is instant, and therefore the impedance Z is equal at each portion of the present invention.

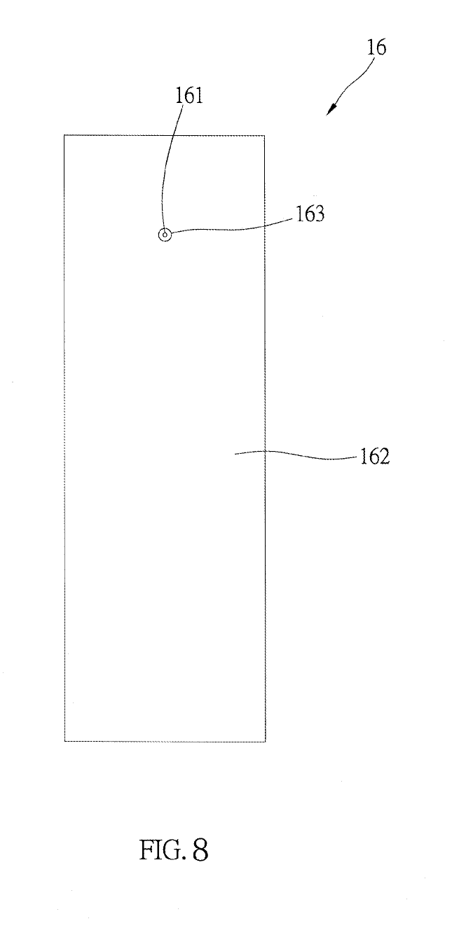

The connecting layer 16 is made of a conductive material, and is disposed on the second surface 122 of the substrate 12, wherein the connecting layer 16 has a signal connecting portion 161 and a ground connecting portion 162 which are mutually separated, as shown in FIG. 8. In the first preferred embodiment, the ground connecting portion 162 has a perforation 163, in which the signal connecting portion 161 is located. In addition, the signal connecting portion 161 is connected to the signal via 123, while the ground connecting portion 162 is connected to the plurality of ground vias 124.

Two opposite ends of the probe 20 are a point end 22 and a connect end 24 respectively, wherein the point end 22 is adapted to touch a test portion of the DUT, and the connect end 24 is connected to the first end 142a of the signal feeding pad 142. In the first preferred embodiment, a diameter φ2 of the connect end 24 is no greater than the width W1 of the first end 142a, and is preferred to be slightly less than the width W1 of the first end 142a. Such design can not only prevent the problem of free welding during installation, but also prevent the problem of current disorder which may happen due to excessive difference between cross-sectional areas when electrical signals passing through where the connect end 24 and the first end 142a are connected, which allows current to flow through more smoothly.

The probe holder 30 is made of an insulating material, and is disposed on the substrate 10, wherein a portion of the probe 20 between the point end 22 and the connect end 24 is embedded in the probe holder 30, while the point end 22 and the connect end 24 are exposed out of the probe holder 30. The reason to provide the probe holder 30 in the present invention is to stabilize the probe 20. In addition, the probe holder 30 separates the probe 20 and other components, and therefore the probe 20 may have better efficiency on transmitting signals.

The connector 40 is disposed on the connecting layer 16, and is electrically connected to the test machine. The connector 40 has a signal transmitting portion 42 and a ground transmitting portion 44, wherein the signal transmitting portion 42 is a metal pin, and is connected to the signal connecting portion 161. In other words, the signal transmitting portion 42 is electrically connected to the probe 20 through the signal connecting portion 161, the signal via 123, and the signal feeding pad 142. The ground transmitting portion 44 is a metal holder surrounding the signal transmitting portion 42, and is connected to the ground connecting portion 162. Similarly, the ground transmitting portion 44 is electrically connected to the ground pad 141 through the ground connecting portion 162 and the plurality of ground vias 124.

With the aforementioned design, such as the width W1 of the first end 142a of the signal feeding pad 142 is slightly greater than the diameter φ2 of the probe connect end 24, the width W2 of the second end 142b of the signal feeding pad 142 is slightly greater than the aperture φ1, and the width of the signal feeding pad 142 is gradually narrower from the second end 142b toward the first end 142a, when an electrical signal passes through where the probe 20 and the first end 142a are connected and where the second end 142b and the signal via 123 are connected, the problem of current disorder which may happen due to excessive differences between cross-sectional areas can be prevented. Furthermore, since the width of the signal feeding pad 142 is gradually narrower, the signal feeding pad 142 may be served as a connecting interface, which allows electrical signals to pass therethrough more smoothly. As a result, the loss while transmitting electrical signals can be effectively reduced, and the accuracy of transmission can be enhanced as well.

In addition, since the matching compensation opening 143 is gradually narrower from the second side 143b toward the first side 143a, the distance between the signal feeding pad 142 and the wall of the matching compensation opening 143 is gradually narrower from the second end 142b toward the first end 142a, too. Therefore, the parasitic capacitance generated between the signal feeding pad 142 and the wall of the matching compensation opening 143 would change in proportion to the parasitic inductance generated along with the width of the signal feeding pad 142, which makes the impedance at each portion of the transmission path equal, and therefore effectively reaches the goal of impedance matching.

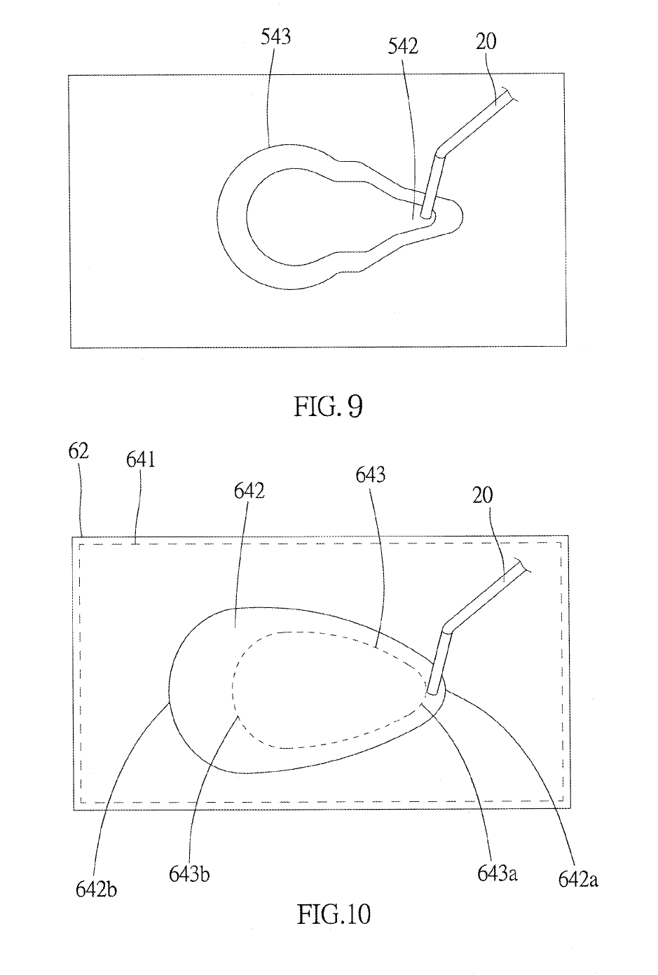

It is worth mentioning that, in addition to the aforementioned design, a signal feeding pad 542 and a matching compensation opening 543 of the second preferred embodiment can be gradually narrower in a ladder shape, as shown in FIG. 9, wherein the probe 20 is also connected to the signal feeding pad 542 at the end of smaller width as mentioned in the first preferred embodiment. In this way, the probe card of the second preferred embodiment can also smoothly transmit electrical signals, and ensure the impedance at each portion of the transmission path is equal as well.

In addition, a signal feeding pad 642 and a ground pad 641 of the third preferred embodiment can be disposed on different layers of the substrate 62, as shown in FIG. 10, to provide the same functions. More specifically, the signal feeding pad 642 is disposed on a surface of the substrate 62, and a width of the signal feeding pad 642 is gradually and linearly narrower from a second end 642b toward a first end 642a thereof, making the signal feeding pad 642 in a shape of a water drop. Similarly, the probe 20 is connected to the first end 642a of the signal feeding pad 642. The ground pad 641 is embedded in the substrate 62, and is separated from the signal feeding pad 642 with a certain distance, wherein the ground pad 641 has a matching compensation opening 643 located at a position aligning to the signal feeding pad 642, and the shape of the matching compensation opening 643 is similar to the shape of the signal feeding pad 642. In this way, a width of the matching compensation opening 643 is gradually narrower from a second side 643b toward a first side 643a thereof. In addition, an area of the matching compensation opening 643 is smaller than an area of the signal feeding pad 642, and therefore the matching compensation opening 643 is located within a projection range of the signal feeding pad 642. With the aforementioned design, electrical signals can be also smoothly transmitted, and the parasitic capacitance between the signal feeding pad 642 and the wall of the matching compensation opening 643 can also change in proportion to the parasitic inductance generated along with the width of the signal feeding pad 642, which makes the impedance at each portion of the transmission path equal, and therefore the goal of impedance matching can be effectively achieved.

It must be pointed out that the embodiments described above are only some preferred embodiments of the present invention, and are not limitations of the present invention. For example, different ways of gradual narrowing mentioned in different preferred embodiments can be correspondingly modified to be adapted to be used for other designs which dispose the signal feeding pad and the ground pad either on the same layer or on different layers of the substrate. As long as the functions of impedance matching and conversion of connecting interfaces can be achieved by using the gradual narrowing shapes of the signal feeding pad and the matching compensation opening, all equivalent structures which employ the concepts disclosed in this specification and the appended claims should fall within the scope of the present invention.

What is claimed is:

1. A probe card adapted to be provided between a DUT and a test machine, comprising:
a connecting circuit board comprising a substrate, a signal feeding structure, and a connecting layer, wherein the substrate has a first surface and a second surface, and the substrate has a plurality of ground vias and a signal via which communicate the first surface and the second surface; the signal feeding structure is made of a conductive material, and is disposed on the first surface of the substrate; the signal feeding structure comprises a ground pad and a signal feeding pad, wherein the ground pad is connected to the plurality of ground vias, and has a matching compensation opening; the matching compensation opening has a first side and a second side, wherein a width of the first side is less than a width of the second side; the signal feeding pad is located in the matching compensation opening without contacting the ground pad; the signal feeding pad has a first end and a second end, wherein the first end is toward the first side, while the second end is toward the second side, and is connected to the signal via; a width of the second end is greater than a width of the first end, and is no less than an aperture of the signal via; a first distance is formed between the first end a wall of the first side, and a second distance is formed between the second end and a wall of the second side, wherein the second distance is longer than the first distance; the connecting layer is made of a conductive material, and is disposed on the second surface of the substrate, wherein the connecting layer has a signal connecting portion and a ground connecting portion which are mutually separated; the signal connecting portion is connected to the signal via, and the ground connecting portion is connected to the plurality of ground vias;
a connector disposed on the connecting layer, wherein the connector is adapted to be electrically connected to the test machine, and has a signal transmitting portion and a ground transmitting portion; the signal transmitting portion is connected to the signal connecting portion, and the ground transmitting portion is connected to the ground connecting portion of the connecting layer; and
a probe having a point end and a connect end, wherein the point end is adapted to touch the DUT, and the connect end is connected to the first end of the signal feeding pad;
a diameter of the connect end is no greater than the width of the first end.

2. The probe card of claim 1, wherein the plurality of ground vias of the substrate surround a region, in which the signal via is located.

3. The probe card of claim 2, wherein an area of the region is greater than an area of the signal feeding pad.

4. The probe card of claim 1, wherein the aperture of the signal via is larger than the aperture of each of the plurality of ground vias.

5. The probe card of claim 1, wherein a width of the signal feeding pad between the second end and the first end is between the width of the first end and the width of the second end.

6. The probe card of claim 5, wherein the width of the signal feeding pad between the second end and the first end is gradually narrower from the second end toward the first end in a linear way.

7. The probe card of claim 1, wherein a width of the matching compensation opening between the second side and the first side is between the width of the first side and the width of the second side.

8. The probe card of claim 7, wherein the width of the matching compensation opening between the second side and the first side is gradually narrower from the second side toward the first side in a linear way.

9. The probe of claim 1, wherein a distance between a portion of the signal feeding pad between the second end and the first end and a wall of the matching compensation opening between the second side and the first side is between the first distance and the second distance.

10. The probe of claim 9, wherein the distance between the portion of the signal feeding pad between the second end and the first end and the wall of the matching compensation opening between the second side and the first side is gradually narrower from the second end toward the first end in a linear way.

11. The probe of claim 5, wherein a distance between a portion of the signal feeding pad between the second end and the first end and a wall of the matching compensation opening between the second side and the first side is between the first distance and the second distance.

12. The probe of claim 11, wherein the distance between the portion of the signal feeding pad between the second end and the first end and the wall of the matching compensation opening between the second side and the first side is gradually narrower from the second end toward the first end in a linear way.

13. The probe of claim 7, wherein a distance between a portion of the signal feeding pad between the second end and the first end and a wall of the matching compensation opening between the second side and the first side is between the first distance and the second distance.

14. The probe of claim 13, wherein the distance between the portion of the signal feeding pad between the second end and the first end and the wall of the matching compensation opening between the second side and the first side is gradually narrower from the second end toward the first end in a linear way.

15. The probe of claim 1, wherein a shape of the signal feeding pad is similar to or the same with a shape of the matching compensation opening.

16. The probe of claim 1, wherein the ground connecting portion of the connecting layer has a perforation, in which the signal connecting portion is located.

17. The probe of claim 1, further comprising a probe holder, which is made of an insulating material, and is disposed on the substrate; a portion of the probe is embedded in the probe holder, and the point end and the connect end are exposed out of the probe holder.

18. A connecting circuit board adapted to be provided between a probe and a connector, wherein the probe has a connect end, and the connector has a signal transmitting portion and a ground transmitting portion; comprising:
a substrate having a first surface and a second surface, wherein the substrate has a plurality of ground vias and a signal via which communicate the first surface and the second surface;
a signal feeding structure made of a conductive material, wherein the signal feeding structure is disposed on the first surface of the substrate; the signal feeding structure comprises a ground pad and a signal feeding pad, wherein the ground pad is connected to the plurality of ground vias, and has a matching compensation opening; the matching compensation opening has a first side and a second side, wherein a width of the first side is less than a width of the second side; the signal feeding pad is located in the matching compensation opening without contacting the ground pad; the signal feeding pad has a first end and a second end, wherein the first end is toward the first side, and is adapted to be connected to the connect end of the probe; a width of the first end is no less than a diameter of the connect end; the second end is toward the second side, and is connected to the signal via; a width of the second end is greater than a width of the first end, and is no less than an aperture of the signal via; a first distance is formed between the first end a wall of the first side, and a second distance is formed between the second end and a wall of the second side, wherein the second distance is longer than the first distance; and
a connecting layer made of a conductive material, wherein the connecting layer is disposed on the second surface of the substrate, wherein the connecting layer has a signal connecting portion and a ground connecting portion which are mutually separated; the signal connecting portion is connected to the signal via and the signal transmitting portion, and the ground connecting portion is connected to the plurality of ground vias and the ground transmitting portion.

19. The connecting circuit board of claim 18, wherein the plurality of ground vias of the substrate surround a region, in which the signal via is located.

20. The connecting circuit board of claim 18, wherein an area of the region is greater than an area of the signal feeding pad.

21. The connecting circuit board of claim 18, wherein the aperture of the signal via is larger than the aperture of each of the plurality of ground vias.

22. The connecting circuit board of claim 18, wherein a width of the signal feeding pad between the second end and the first end is between the width of the first end and the width of the second end.

23. The connecting circuit board of claim 22, wherein the width of the signal feeding pad between the second end and the first end is gradually narrower from the second end toward the first end in a linear way.

24. The connecting circuit board of claim 18, wherein a width of the matching compensation opening between the second side and the first side is between the width of the first side and the width of the second side.

25. The connecting circuit board of claim 24, wherein the width of the matching compensation opening between the second side and the first side is gradually narrower from the second side toward the first side in a linear way.

26. The connecting circuit board of claim 18, wherein a distance between a portion of the signal feeding pad between the second end and the first end and a wall of the matching compensation opening between the second side and the first side is between the first distance and the second distance.

27. The connecting circuit board of claim 26, wherein the distance between the portion of the signal feeding pad between the second end and the first end and the wall of the matching compensation opening between the second side and the first side is gradually narrower from the second end toward the first end.

28. The connecting circuit board of claim 22, wherein a distance between a portion of the signal feeding pad between the second end and the first end and a wall of the matching compensation opening between the second side and the first side is between the first distance and the second distance.

29. The connecting circuit board of claim 28, wherein the distance between the portion of the signal feeding pad between the second end and the first end and the wall of the matching compensation opening between the second side and the first side is gradually narrower from the second end toward the first end.

30. The connecting circuit board of claim 24, wherein a distance between a portion of the signal feeding pad between the second end and the first end and a wall of the matching compensation opening between the second side and the first side is between the first distance and the second distance.

31. The connecting circuit board of claim 30, wherein the distance between the portion of the signal feeding pad between the second end and the first end and the wall of the matching compensation opening between the second side and the first side is gradually narrower from the second end toward the first end.

32. The connecting circuit board of claim 18, wherein a shape of the signal feeding pad is similar to or the same with a shape of the matching compensation opening.

33. The connecting circuit board of claim 18, wherein the ground connecting portion of the connecting layer has a perforation, in which the signal connecting portion is located.

34. A signal feeding structure adapted to connect a connect end of a probe and a signal via of a substrate; comprising:
a ground pad made of a conductive material, wherein the ground pad is disposed on the substrate, and has a matching compensation opening which goes through the ground pad; the matching compensation opening has a first side and a second side, wherein a width of the first side is less than a width of the second side; and
a signal feeding pad made of a conductive material, wherein the signal feeding pad is disposed on the substrate and is in the matching compensation opening without contacting the ground pad; the signal feeding pad has a first end and a second end, wherein the first end is toward the first side, and is adapted to be connected to the connect end of the probe; a width of the first end is no less than a diameter of the connect end; the second end is toward the second side, and is connected to the signal via; a width of the second end is greater than a width of the first end, and is no less than an aperture of the signal via; a first distance is formed between the first end a wall of the first side, and a second distance is formed between the second end and a wall of the second side, wherein the second distance is longer than the first distance.

35. The signal feeding structure of claim 34, wherein a width of the signal feeding pad between the second end and the first end is between the width of the first end and the width of the second end.

36. The signal feeding structure of claim 35, wherein the width of the signal feeding pad between the second end and the first end is gradually narrower from the second end toward the first end in a linear way.

37. The signal feeding structure of claim 34, wherein a width of the matching compensation opening between the second side and the first side is between the width of the first side and the width of the second side.

38. The signal feeding structure of claim 37, wherein the width of the matching compensation opening between the second side and the first side is gradually narrower from the second side toward the first side in a linear way.

39. The signal feeding structure of claim 34, wherein a distance between a portion of the signal feeding pad between the second end and the first end and a wall of the matching compensation opening between the second side and the first side is between the first distance and the second distance.

40. The signal feeding structure of claim 39, wherein the distance between the portion of the signal feeding pad between the second end and the first end and the wall of the matching compensation opening between the second side and the first side is gradually narrower from the second end toward the first end.

41. The signal feeding structure of claim 35, wherein a distance between a portion of the signal feeding pad between the second end and the first end and a wall of the matching compensation opening between the second side and the first side is between the first distance and the second distance.

42. The signal feeding structure of claim 41, wherein the distance between the portion of the signal feeding pad between the second end and the first end and the wall of the matching compensation opening between the second side and the first side is gradually narrower from the second end toward the first end.

43. The signal feeding structure of claim 37, wherein a distance between a portion of the signal feeding pad between the second end and the first end and a wall of the matching compensation opening between the second side and the first side is between the first distance and the second distance.

44. The signal feeding structure of claim 43, wherein the distance between the portion of the signal feeding pad between the second end and the first end and the wall of the matching compensation opening between the second side and the first side is gradually narrower from the second end toward the first end.

45. The signal feeding structure of claim 34, wherein a shape of the signal feeding pad is similar to or the same with a shape of the matching compensation opening.
